(19) United States
(12) Patent Application Publication
(10) Pub. No.: US 2026/0005017 A1
(43) Pub. Date: Jan. 1, 2026

(54) METHODS FOR FORMING A DOPED HIGH-K LAYER ON A SUBSTRATE

(71) Applicant: ASM IP Holding B.V., Almere (NL)

(72) Inventors: Rohit Abraham John, Chandler, AZ (US); Fu Tang, Gilbert, AZ (US); Eric James Shero, Phoenix, AZ (US)

(21) Appl. No.: 19/251,984

(22) Filed: Jun. 27, 2025

Related U.S. Application Data
(60) Provisional application No. 63/665,965, filed on Jun. 28, 2024.

(51) Int. Cl. H01L 21/02; C23C 16/40; C23C 16/44; C23C 16/455

(52) U.S. Cl. CPC H01L 21/0228; C23C 16/40; C23C 16/4408; C23C 16/45531; H01L 21/02181; H01L 21/02189; H01L 21/02194

(57) ABSTRACT

Disclosed herein is a method, system and apparatus for forming, by a cyclic process, a dopant concentration gradient in a doped hafnium zirconium oxide (HZO) layer on a substrate, the cyclic process includes, providing the substrate in a reaction chamber, a) pulsing a hafnium precursor(s) into the reaction chamber, where at least a part of the substrate is contacted with the hafnium precursor(s), b) pulsing a zirconium precursor(s) into the reaction chamber, where at least a part of the substrate is contacted with the zirconium precursor(s), c) pulsing an oxygen reactant(s) into the reaction chamber, where at least a part of the substrate is contacted with the oxygen reactant(s), d) pulsing a dopant precursor(s) into the reaction chamber, where at least a part of the substrate is contacted with the dopant precursor(s), and e) purging the reaction chamber.

### CROSS-REFERENCE TO RELATED APPLICATIONS

This application is a nonprovisional of, and claims priority to and the benefit of, U.S. Provisional Patent Application No. 63/665,965, filed Jun. 28, 2024 and entitled “METHODS FOR FORMING A DOPED HIGH-K LAYER ON A SUBSTRATE,” which is hereby incorporated by reference herein.

### TECHNICAL FIELD

The present disclosure generally relates to the field of capacitor devices. More particularly, to Metal-Insulator-Metal capacitors (MIM CAPS) comprising a Hafnium Zirconium Oxide (HZO) layer, and a method for producing the same.

### BACKGROUND OF THE DISCLOSURE

The semiconductor industry is continually pushing the boundaries of miniaturization, and with this comes the challenge of maintaining performance while managing power consumption and reliability. High dielectric constant (k) gate oxides are pivotal in this endeavor, especially for advanced technology nodes like FinFETs, Gate-All-Around (GAAs), and Complementary FETs (CFETs). These materials allow for a reduced Equivalent Oxide Thickness (EOT), which is crucial for enhancing device performance without increasing leakage currents. Hafnium oxide (HfO) has been the standard, but as the industry moves towards even thinner gate oxides, Hafnium Zirconium Oxide (HfZrO) emerges as a promising alternative due to its higher k-value. However, HfZrO is not without its challenges; it exhibits high CV non-linearities and asymmetry stemming from the interplay between Ferroelectric (FE) and Anti-Ferroelectric (AFE) behaviors. This becomes particularly problematic as the film thickness decreases below 45 angstroms, where leakage currents exceed acceptable limits, and the issue exacerbates for films around 15-20 angstroms, which are typical in the industry.

To address the leakage issues in these ultra-thin films, the industry has relied on Post Deposition Anneal (PDA) processes. While PDA can help reduce leakage, it presents a narrow process window that is challenging to control with precision, leading to integration difficulties. Thus, a need remains to address leakage issues with reduced integration failures.

Likewise, miniaturization of capacitors, specifically Metal-Insulator-Metal capacitors (MIM CAPS), presents similar challenges. Capacitors are electrical components characterized by a constant capacitance, C, and are composed of at least two electrical conductors (electrodes) separated by an insulating layer. The insulator increases the capacitor's charge capacity, and the capacitance is influenced by the geometry of the conductors, the distance between them, and the permittivity of the insulating material.

The highest capacitance is achieved with a high permittivity dielectric material, large plate area, and small separation between the plates. The relative permittivity is important in capacitor design, and materials with high relative permittivity reduce the magnitude of an electric field within the dielectric's volume, thereby increasing the capacitance.

There is a desire for a high dielectric constant value (K), linear and symmetric Capacitance Voltage (CV) characteristic, and high capacitance density for next-generation MIM CAPS for logic and memory applications. Using a ferroelectric/antiferroelectric Hafnium Zirconium Oxide (HZO) layer can provide a dielectric constant value k above 40. However, these capacitors have a non-linear CV characteristic, causing a peak of the dielectric constant value K around OV, while the value k at other desired fields may be significantly lower. This non-linearity makes integration into devices or circuits challenging, indicating a need for alternative materials with more linear CV characteristics and a peak of the dielectric constant value k in a desired field.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein a method, system and apparatus for forming, by a cyclic process, a dopant concentration gradient in a doped hafnium zirconium oxide (HZO) layer on a substrate, the cyclic process includes, providing the substrate in a reaction chamber, a) pulsing one or more hafnium precursors into the reaction chamber, where at least a part of the substrate is contacted with the one or more hafnium precursors, b) pulsing one or more zirconium precursors into the reaction chamber, where at least a part of the substrate is contacted with the one or more zirconium precursors, c) pulsing an oxygen reactant into the reaction chamber, where at least a part of the substrate is contacted with the one or more oxygen reactants, d) pulsing one or more dopant precursors into the reaction chamber, where at least a part of the substrate is contacted with the one or more dopant precursors, and e) purging the reaction chamber. The method further includes repeating one or more of operations a), b), c), d), or e), or a combination thereof, in any order, until the doped HZO layer having a first predetermined thickness is deposited on the substrate. The method further includes tuning a pulse ratio of the dopant precursor versus one or more of, the one or more hafnium precursors, the one or more zirconium precursors, or the oxygen reactant, or a combination thereof, and forming the dopant concentration gradient responsive to the tuning. The method further includes where the forming the dopant concentration gradient includes varying a flow rate of the dopant precursor. The method further includes where the forming the dopant concentration gradient includes tuning a pulse ratio of the one or more dopant precursors versus the one or more hafnium precursors, the one or more zirconium precursors and the oxygen reactant, or a combination thereof, to introduce the dopant precursor at a varied concentration within the HZO layer. The method further includes where the concentration of the dopant element in the HZO layer ranges between 0.0 to 20.0% from a first interface to a second interface, where the concentration of the dopant element is lowest proximate the first interface and highest proximate the second interface. The method further includes where the concentration of the dopant element in the HZO layer ranges between 0.0 to 20.0% from a first interface to a second interface, where the concentration of the dopant element is lowest proximate the first interface and highest proximate the second interface. The method further includes where the dopant precursor includes a dopant element characterized by having three or four valence electrons and an atomic radius which is less than the atomic radius of an Hf or Zr element of the HZO layer. The method further includes where said dopant element is selected from the list consisting of Aluminium, Silicon, Nickel, Germanium, Gallium and Carbon. The method further includes where the method further includes providing a seed layer prior to forming the doped HZO layer, said seed layer being a ZrO2 seed layer. The method further includes where said substrate includes a Metal Oxide (MO) surface layer, where said method further includes the step of forming a Metal Oxide (MO) top layer on the doped HZO layer, thereby forming a layered doped HZO structure, where the MO surface layer and/or the MO top layer is in direct contact with the doped HZO layer, where the metal oxide is titanium oxide (e.g., TiO2). The method further includes where said doped HZO layer increases the dielectric constant value (K) of the doped HZO layer with respect to the HZO layer without the dopant. The method further includes where said dopant element is selected from the list consisting of Aluminium, Silicon, Nickel, Germanium, Gallium and Carbon. Other technical features may be readily apparent to one skilled in the art from the following figures, descriptions, and claims. In one aspect, a method includes providing a substrate in a reaction chamber, forming a nanolaminate structure on the substrate includes a first hafnium zirconium oxide (HZO) sub-layer and a second hafnium zirconium oxide (HZO) sub-layer, by a cyclic process, the cyclic process includes, a) pulsing one or more hafnium precursors into the reaction chamber, where at least a part of the substrate is contacted with the one or more hafnium precursors, b) pulsing one or more zirconium precursors into the reaction chamber, where at least a part of the substrate is contacted with the one or more zirconium precursors, c) pulsing an oxygen reactant into the reaction chamber, where at least a part of the substrate is contacted with the one or more oxygen reactants, and d) purging the reaction chamber, where the first HZO sub-layer and the second HZO sub-layer comprise different concentrations of Hf and different concentrations of Zr. The method further includes where the pulsing the one or more dopant precursors into the reaction chamber further includes depositing a first concentration of dopant elements proximate to a surface or interface of the HZO layer, where forming the doped HZO layer further includes forming the dopant concentration gradient by exposing the substrate to an annealing process. The method further includes where the annealing is subsequent to depositing the first concentration of dopant elements. The method further includes further includes forming a first HZO sub-layer having a first concentration of dopant elements and a second HZO sub-layer having a second concentration of the dopant elements, where the first concentration of dopant elements is different from the second concentration of dopant elements. The method further includes further includes repeating one or more of operations a), b), c), or d), or a combination thereof, in any order, until the first HZO layer having a first predetermined thickness and the second HZO layer includes a second predetermined thickness are deposited on the substrate. The method further includes further includes varying a flow rate of the one or more hafnium precursors or varying a pulse ratio of the one or more hafnium precursors, the one or more zirconium precursors and the oxygen reactant, or a combination thereof to deposit a first concentration of Hf in the first HZO sub-layer and deposit a second concentration of Hf in the second HZO sub-layer. The method further includes where the first concentration of Hf is greater than the second concentration of Hf. The method further includes varying a flow rate of the one or more zirconium precursors or varying a pulse ratio of the one or more hafnium precursors, the one or more zirconium precursors and the oxygen reactant, or a combination thereof to deposit a first concentration of Zr in the first HZO sub-layer and deposit a second concentration of Zr in the second HZO sub-layer. The method further includes the first concentration of Zr is less than the second concentration of Zr. The method further includes doping the nanolaminate structure responsive to k) pulsing one or more dopant precursors into the reaction chamber, where at least a part of the substrate is contacted with the one or more dopant precursors. The method further includes forming a dopant concentration gradient within the nanolaminate structure responsive to varying a flow rate of the one or more dopant precursors or tuning a pulse ratio of the one or more dopant precursors versus one or more of, the one or more hafnium precursors, the one or more zirconium precursors, or the oxygen reactant, or a combination thereof. The method further includes where forming the dopant concentration gradient within the nanolaminate structure further includes imparting a first concentration of dopant elements into the first HZO sub-layer and imparting a second concentration of dopant elements into the second HZO sub-layer, where the first concentration of dopant elements is different from the second concentration of dopant elements. The method further includes where the concentration of the dopant element in the doped HZO nanolaminate structure ranges between 0.0 to 15.0% from a first interface to a second interface, where the concentration of the dopant element is lowest proximate the first interface and highest proximate the second interface. The method further includes where the dopant precursor includes a dopant element characterized by having three or four valence electrons and an atomic radius which is less than the atomic radius of an Hf or Zr element of the HZO layer. The method further includes where the method further includes providing a seed layer prior to forming said doped HZO nanolaminate structure, said seed layer being a ZrO2 seed layer. The method according to claim 18, where the substrate includes a Metal Oxide (MO) surface layer, where the method further includes forming a Metal Oxide (MO) top layer on the doped HZO nanolaminate structure, thereby forming a layered doped HZO structure, where the MO surface layer or the MO top layer is in direct contact with the doped HZO nanolaminate structure, where said metal oxide is titanium oxide (e.g., TiO, TiO2). The method further includes where said doped HZO layer decreases leakage with respect to the HZO layer without the dopant. The method further includes where the doped HZO layer increases the dielectric constant value (K) and decreases the leakage with respect to the HZO layer without the dopant. The method further includes one or more additional HZO sub-layers each having a different concentration of dopant elements from other HZO sub-layers, and the first or second HZO sub-layer. Other technical features may be readily apparent to one skilled in the art from the following figures, descriptions, and claims.

These and other embodiments will become readily apparent to those skilled in the art from the following detailed description of certain embodiments having reference to the attached figures; the invention not necessarily being limited to any particular embodiment(s) disclosed.

### BRIEF DESCRIPTION OF THE FIGURES

A more complete understanding of exemplary embodiments of the present disclosure can be derived by referring to the detailed description and claims when considered in connection with the following illustrative figures.

FIG. 1 describes an exemplary embodiment of a method for forming a doped hafnium zirconium oxide (HZO) layer on a substrate.

FIG. 2A illustrates a first modification to a CV curve by doping the HZO layer according to the disclosure, FIG. 2B illustrates a second modification to a CV curve by doping the HZO layer according to the disclosure, and FIG. 2C illustrates a third modification to a CV curve by doping the HZO layer according to the disclosure.

FIG. 2D illustrates a symmetrized CV curve of a doped HZO layer deposited on a seed layer according to the disclosure.

FIG. 3 schematically shows an exemplary MIM capacitor 300 of the disclosure.

FIG. 4 schematically illustrates another exemplary MIM capacitor 400 of the disclosure.

FIG. 5 schematically illustrates a further exemplary MIM capacitor 500 of the disclosure.

FIG. 6 schematically illustrates a system 600 in accordance with yet additional exemplary embodiments of the disclosure.

FIG. 7 schematically illustrates an exemplary device 700 of the disclosure.

FIG. 8 schematically illustrates an exemplary device 800 of the disclosure.

FIG. 9 schematically illustrates an exemplary device 900 of the disclosure.

FIG. 10 schematically illustrates an exemplary device 1000 of the disclosure.

FIG. 11 schematically illustrates an exemplary device 1100 of the disclosure.

FIG. 12 schematically illustrates an exemplary device 1200 of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

The term “halo” or “halogen” as a group or part of a group is generic for fluoro (F), chloro (Cl), bromo (Br), iodo (I).

The term “alkyl” as a group or part of a group, refers to a hydrocarbyl group of formula CnH2n+1 wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C1-20alkyl”, as a group or part of a group, refers to a hydrocarbyl group of formula —CnH2n+1 wherein n is a number ranging from 1 to 20. Thus, for example, “C1-8alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e. “alkylene”, this is intended to mean the alkyl group as defined herein having two single bonds as points of attachment to other groups. As used herein, the term “alkylene” also referred as “alkanediyl”, by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH2-), ethylene (—CH2-CH2-), methylmethylene (—CH(CH3)-), 1-methyl-ethylene (—CH(CH3)-CH2-), n-propylene (—CH2-CH2-CH2-), 2-methylpropylene (—CH2-CH(CH3)-CH2-), 3-methylpropylene (—CH2-CH2-CH(CH3)-), n-butylene (—CH2-CH2-CH2-CH2-), 2-methylbutylene (—CH2-CH(CH3)-CH2-CH2-), 4-methylbutylene (—CH2-CH2-CH2-CH(CH3)-), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C3-20alkenyl groups are ethenyl, 2-propenyl, 2-butenyl, 3-butenyl, 2-pentenyl and its isomers, 2-hexenyl and its isomers, 2,4-pentadienyl, and the like.

The term “cycloalkyl”, as a group or part of a group, refers to a cyclic alkyl group, that is a monovalent, saturated, hydrocarbyl group having 1 or more cyclic structure, and comprising from 3 to 20 carbon atoms, more preferably from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C3-20cycloalkyl”, a cyclic alkyl group comprising from 3 to 20 carbon atoms. For example, the term “C3-10cycloalkyl”, a cyclic alkyl group comprising from 3 to 10 carbon atoms. For example, the term “C3-8cycloalkyl”, a cyclic alkyl group comprising from 3 to 8 carbon atoms. For example, the term “C3-6cycloalkyl”, a cyclic alkyl group comprising from 3 to 6 carbon atoms. Examples of C3-12cycloalkyl groups include but are not limited to adamantly, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

When the suffix “ene” is used in conjunction with a cycloalkyl group, i.e. cycloalkylene, this is intended to mean the cycloalkyl group as defined herein having two single bonds as points of attachment to other groups. Non-limiting examples of “cycloalkylene” include 1,2-cyclopropylene, 1,1-cyclopropylene, 1,1-cyclobutylene, 1,2-cyclobutylene, 1,3-cyclopentylene, 1,1-cyclopentylene, and 1,4-cyclohexylene.

Where an alkylene or cycloalkylene group is present, connectivity to the molecular structure of which it forms part may be through a common carbon atom or different carbon atom. To illustrate this applying the asterisk nomenclature of this disclosure, a C3alkylene group may be for example *—CH2CH2CH2-*, *—CH(—CH2CH3)-* or *—CH2CH(—CH3)-*. Likewise, a C3cycloalkylene group may be

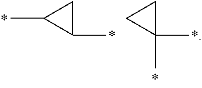

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C6-20aryl, preferably C6-10aryl, more preferably C6-8aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The term “alkoxy” or “alkyloxy”, as a group or part of a group, refers to a group having the formula —ORb wherein Rb is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

The term “heteroalkyl” as a group or part of a group, refers to an acyclic alkyl wherein one or more carbon atoms are replaced by at least one heteroatom selected from the group comprising O, Si, S, B, and P, with the proviso that the chain may not contain two adjacent heteroatoms. This means that one or more —CH3 of the acyclic alkyl can be replaced by —OH for example and/or that one or more —CR2- of the acyclic alkyl can be replaced by O, Si, S, B, and P.

The term “cyclopentadienyl” as a group or part of a group, refers to a group having the formula (V)

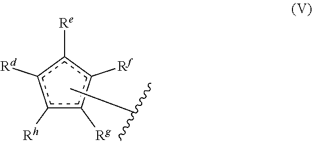

wherein Rd, Re, Rf, Rg, Rh are each independently selected from the group consisting of hydrogen, alkyl, alkenyl, alkoxy, or heteroalkyl as defined herein above. As disclosed herein, cyclopentadienyl is a 5-member carbon ring bound to metal such as hafnium and/or zirconium through covalent n5-bonds. Thus, for example, “cyclopentadienyl” refers to both hydrogenated cyclopenta-2,4-dien-1-yl (Cp) and substituted cyclopenta-2,4-dien-1-yl, such as, methyl-cyclopenta-2,4-dien-1-yl (MeCp), ethyl-cyclopenta-2,4-dien-1-yl (EtCp), and n-propyl-cyclopenta-2,4-dien-1-yl (n-PrCp).

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C6-20aryl, preferably C6-10aryl, more preferably C6-8aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in the chemical reaction that produces another compound, particularly a compound that constitutes a film matrix or a main skeleton of a film; the term “reactant” can be used interchangeably with the precursor.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In this disclosure, the following abbreviations of chemical structures are used: Cp stands for cyclopentadienyl, Me stands for methyl; Et stands for ethyl; n-Pr stands for n-propyl; i-Pr stands for i-propyl or isopropyl, n-Bu stands for n-butyl; t-Bu stands for t-butyl or tert-butyl.

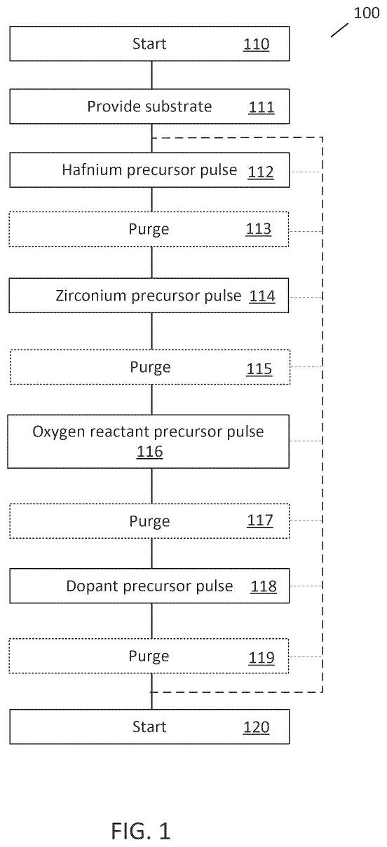

Turning now to the figures, FIG. 1 illustrates a method 100 in accordance with exemplary embodiments of the disclosure. In general, the technology disclosed herein relates to the field of transistor and capacitor devices, and more specifically to a method for forming a transistor and/or capacitor structure comprising a doped HZO layer. An important step of the doped HZO layer formation referred to herein can comprise the selection of an appropriate dopant precursor which comprises three or four valence electrons and an atomic radius which is less than the atomic radius of an Hf or Zr element of the HZO layer. Advantageously, the disclosed method alters the CV curve, resulting in a dielectric constant value k at a desired high level and within a desired voltage range, while still experiencing low leakage. To elaborate, one of the challenges in doped HZO layers is to push ferroelectric HZO into an antiferroelectric conduction, which boost the dielectric constant k at the desired voltage thus shifting the CV curve so that a high k at a desired voltage can be reached. In contrast to the state of the art, the current disclosure allows to design a doped HZO layer by using appropriate dopants such that the ferroelectric properties of the HZO layer are changed to a primarily tetragonal composition, thus shifting the maximum dielectric constant k to the region of interest, which boosts the dielectric constant k in the region needed compared to a undoped HZO layer.

As set forth in more detail below, various embodiments of the present disclosure relate to a method for forming a doped hafnium zirconium oxide (HZO) layer on a substrate, the method comprising the steps of:
providing a substrate in a reaction chamber;
executing one or more cycles, a cycle comprising
a hafnium precursor pulse, wherein at least a part of the substrate is contacted with one or more hafnium precursor by introducing said one or more hafnium precursor in the reaction chamber;
a zirconium precursor pulse, wherein at least a part of the substrate is contacted with one or more zirconium precursor by introducing said one or more zirconium precursor in the reaction chamber;
an oxygen reactant pulse, wherein at least a part of the substrate is contacted with one or more oxygen reactant by introducing said one or more oxygen reactant in the reaction chamber; and
a dopant precursor pulse, wherein at least a part of the substrate is contacted with one or more dopant precursor by introducing said one or more dopant precursor in the reaction chamber, thereby forming a doped HZO layer;
wherein said dopant precursor comprises a dopant element characterized by having three or four valence electrons and an atomic radius which is less than the atomic radius of an Hf or Zr element of the HZO layer.

FIG. 1 describes an example of a method 100 for forming a doped hafnium zirconium oxide (HZO) layer on a substrate. The method can include additional steps, may be repeated, and need not be performed in the illustrated sequence nor the same sequence in each repetition if repeated. One or more steps may be repeated any appropriate number of times, for example to create a dopant gradient or higher or lower concentrations of one a particular constituent such as Hf with respect to another over another such as Zr, for example in deposition of one or more nanolaminar films having different concentrations of Hf and Zr.

Method 100 in a cyclical deposition process and starts 110 with providing a substrate in a reaction chamber 111. The cyclical deposition process comprises contacting at least a part of the substrate with a hafnium precursor in a hafnium precursor pulse 112. Optionally, the reaction chamber is purged 113 after hafnium precursor pulse 112. Method 100 includes a zirconium precursor pulse 114 wherein a zirconium precursor is provided to the reaction chamber contacting at least a part of the substrate. Optionally, the reaction chamber can be purged 115 after the zirconium precursor pulse. Further, method 100 comprises providing an oxygen reactant pulse 116 to the reaction chamber contacting at least a part of the substrate. Optionally, the reaction chamber can be purged 117 after the oxygen reactant pulse. Method 100 includes providing a dopant precursor to the reaction chamber in a dopant precursor pulse 118 to contact at least a part of the substrate. Optionally, the reaction chamber can be purged 119 after the dopant precursor pulse. At operation 121, the hafnium precursor pulse 112, the zirconium precursor pulse 114, the oxygen reactant pulse 116, the dopant precursor pulse 118, and the optional purges 113,115,117,119 may be repeated or omitted, as needed, any number of times, for deposition of a doped HZO layer with a specific thickness, dopant concentration, dopant gradient, and/or any number of nanolaminar films containing selected concentrations of Hf, Zr, and dopants. The repetition or omission of the hafnium precursor pulse 112, the zirconium precursor pulse 114, the oxygen reactant pulse 116, the dopant precursor pulse 118, and the optional purges 113,115,117,119 can be adjusted to achieve the desired properties of the layer. When a doped HZO containing layer having a desired thickness, a desired dopant concentration, a desired dopant gradient, a desired number of nanolaminar films comprising selected concentrations of Hf, Zr, and dopants has been deposited, method 100 ends 120. Once the method has ended, the substrate can, for example, be subjected to additional processes to form a device structure and/or device.

In particular, the formation of a doped HZO layer on a substrate as described herein relates to a cyclical deposition process, such as an atomic layer deposition (ALD) process or a cyclical chemical vapor deposition process. ALD is a thin-film technique used to create extremely thin and precise layers of materials on substrates such that a uniform and well-controlled layer can be created on three-dimensional surfaces. Such a cyclical deposition process may comprise one or more cycles, whereby the steps may be repeated from at least 1 cycle to at most 1000 cycles, or from at least 2 cycles to at most 100 cycles, or from at least 5 cycles to at most 50 cycles. The skilled person understands that different orders of pulses within one cycle may be possible.

As used herein, the term “deposition” or “cyclic deposition” or “cyclic deposition process” or “cyclical deposition process” refers to a sequential introduction of precursors into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component. The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Generally, for ALD processes, during each cycle, a (metal) precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present disclosure allows to form dipole layers that do not require full film closure to work. Hence, allowing faster deposition with a larger error-tolerance compared to what is disclosed in the state of the art.

In preferred embodiments, a deposition process as disclosed herein refers to an atomic layer deposition process. Typically, one deposition cycle may form a film or layer of about 0.10 nm. However, the experimental thickness may vary depending on the amount and type of cycles and available reaction sites on the substrate. In preferred embodiments, the method as disclosed herein provides that the HZO layer has an average thickness of 1 nm or less, or 0.75 nm or less, preferably 0.50 nm or less, or 0.4 nm or less, or 0.3 nm or less, preferably 0.25 nm or less, or 0.2 nm or less, more preferably 0.10 nm or less. In some embodiments, the HZO layer is grown at a rate of 0.10 nm or less per alternating pulses of precursor(s)/reactive gas(es), and purge (e.g., inert carrier) gas(es).

In order to create a doped HZO layer on a substrate, a first pulse with a hafnium precursor, a second pulse with a zirconium precursor, and a third pulse with an oxygen reactant are introduced inside the reaction chamber such that at least part of the substrate is in contact with the hafnium precursor, zirconium precursor, oxygen reactant and/or dopant precursor to form a desired thin film. A precursor pulse typically lasts from at least 0.01 s to at most 120 s, while an oxygen reactant pulse lasts from at least 0.1 s to at most 20 s. One precursor will typically react with the substrate's surface, while the other precursors remain inert during that reaction. During the repeated deposition cycles, the precursors are introduced one at a time, allowing them to react with the surface in a self-limiting manner. When the first precursor is introduced, it reacts with the substrate's surface, forming a chemisorbed layer. Typically, excess precursor is purged or removed from the reaction chamber before the next precursor is introduced, which will then react with the already formed chemisorbed layer from the previous step, thus forming a new layer. Once all available reactive sites on the substrate's surface are saturated, the reaction will stop and a thin film which has grown atom-by-atom is created, ensuring precise control over the film thickness.

In order to develop a material having a linear CV characteristic and a dielectric constant value K above 40 in a specific voltage range, a dopant precursor pulse is added to the reaction chamber such that at least a part of the substrate is contacted with one or more dopant precursor, thereby forming a doped HZO layer. Such a doped HZO layer is thus a layer of material formed of hafnium oxide (HfO2) on a substrate that has intentionally been modified or doped with certain elements or impurities. Doping involves introducing small amounts of specific atoms or ions into the host material's crystal lattice. This modification can alter the material's electrical, optical or other properties to suit desired functionalities. When using dopants to improve the electrical performances, typically the dielectric constant value k is enhanced, as well as reducing current leakage and improving its interference with other materials in e.g. semiconductor devices.

When using a dopant precursor comprising a dopant element having three or four valence electrons and an atomic radius which is less than the atomic radius of an Hf or Zr element of the HZO layer, it is possible to push the HZO material into an appropriate Morphotropic Phase Boundary (MPB). Thus, doping the HZO layer with small ionic radius elements stabilizes the tetragonal phase of the HZO layer such that a Morphotropic Phase Boundary (MPB) is reached between the orthorhombic and tetragonal phases of the HZO layer to allow a change in the polarization switching voltage of the HZO layer. At a certain percentage of added dopant, the material adopts a primarily tetragonal phase composition, which results in a boost in the dielectric constant value K of the HZO layer to peak at the voltage region of interest. Additionally, changing the polarization switching voltage of the HZO layer changes the Capacitance Voltage (CV) linearity of the HZO layer, thus tuning the shape of the capacitance-voltage (CV) curve, and arriving at a better linearity. Ideally, the dielectric constant value (K) of said doped HZO layer is above 35 at about −2 and −3 MV/cm.

The MPB is a compositional region within a phase diagram of materials, where a drastic change in the crystal structure and properties can occur as the composition of the material is varied. Different crystal structures can exhibit distinct electrical, mechanical, and thermal properties. The MPB represents a composition range where two different crystal phases coexist, and relative small changes in composition lead to significant changes in changes in the properties of the material. Ferroelectric, antiferroelectric, and paraelectric phases are different phases of the MPB and each have a different ordering of crystals in these materials. These phases relate to how electric dipoles within the material are aligned or ordered, which in turn affects their electrical, mechanical, and thermal properties. In a ferroelectric material, electric dipoles, being molecular or atomic arrangements with positive and negative charges separated, can spontaneously align in a particular direction even in the absence of an external electric field. This alignment gives rise to a permanent electric polarization that can be reversed when an external electric field is applied in the opposite direction.

In an antiferroelectric material, neighboring dipoles have opposite directions of alignment, meaning that the net polarization of the material is zero. When an external electric field is applied, the dipoles tend to align in the direction opposite to that of the field. Antiferroelectric materials are characterized by their abrupt changes in polarization.

In a paraelectric material, there is no spontaneous polarization at all. However, when an external electric field is applied, the material can become polarized temporarily. The polarization disappears when the field is removed. Paraelectric materials exhibit a linear relationship between polarization and electric field and are therefore often used as dielectric materials in capacitors.

These different phases can exist in certain materials due to the arrangement of their atoms or molecules and the interaction between them. The phase transitions between these different states can have profound effects on the material's properties, and understanding and controlling these transitions are crucial when designing capacitors and utilizing these materials for various applications.

Therefore, when doping the HZO layer with selected elements at precise concentrations, the antiferroelectric/paraelectric phase boundary can be triggered and the appropriate crystal structure can be achieved. In some examples, when a dopant element having three or four valence electrons and an atomic radius which is less than the atomic radius of an Hf or Zr element of the HZO layer is used to create a doped HZO layer, a primary tetragonal phase composition is triggered in the formed material. The dominant or primary crystal structure of the material is then tetragonal, whereby the crystals have three axes of different length, two of which are equal and perpendicular to each other, and the third is longer or shorter, while the angles between the axes are all right angles. By doping the HZO layer using such a dopant precursor, a primary tetragonal phase composition of the HZO layer will occur which allow for a shift of the maximum dielectric constant value k such that a peak of the value k at the region of interest is accomplished, will having a nearly flat CV characteristics.

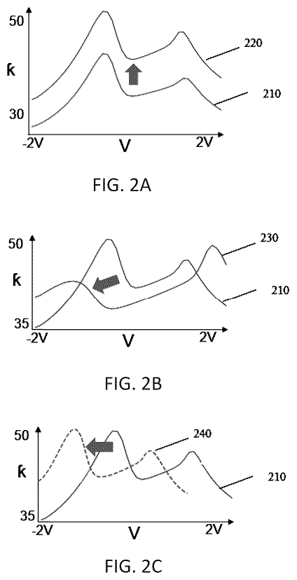

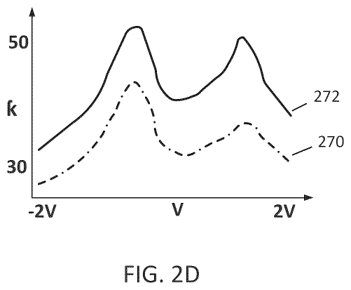

FIGS. 2A-2C illustrate the different modifications possible to a CV curve by doping the HZO layer. In FIG. 2A, a first type of dopant is used to bring the CV curve of an undoped HZO layer 210 up. By doing so, the shape of the CV curve of the doped HZO layer 220 remains essentially the same, however an increase in the value K at approximately the same voltage is achieved. In some examples, using Al as dopant can create this effect. Doping the HZO layer with an Al dopant precursor has the effect that the non-polar phases are reduced due to oxygen vacancy formation and a MPB with approximately a 50%-50% orthorhombic and tetragonal phase composition is achieved. The dopant precursor preferably being a low-reactivity Aluminium precursor represented by the general formula Al(R1)3, wherein each R1 independently selected from the group consisting of hydrogen, halogen, alkyl, alkenyl, N(R2)2, cycloalkyl, and alkoxy; and wherein each R2 is chosen from hydrogen, alkyl, or alkenyl.

In FIG. 2B, a second type of dopant is used to stretch the CV curve of an undoped HZO layer 210. By doing so, the shape of the CV curve of the doped HZO layer 230 changes so that the peaks shift to higher fields while reducing the maximum value of K. In some examples, using Si as dopant can create this effect. Doping the HZO layer with a Si dopant precursor has the effect that the tetragonal phase and the barrier between the polar states is increased. The increase in the tetragonal phase is due to strain and a smaller electronegativity effect which makes it more difficult to polarize the lattice. This has the result that a moderate high k value is reached at a different voltage than with an undoped HZO layer. The dopant precursor preferably being a low-reactivity Silicon precursor selected from the list consisting of silicon tetraacetate (Si(OOCCH3)4), and Si(R3)4, wherein each R3 is independently selected from the group consisting of hydrogen, halogen, alkyl, alkenyl, N(R4)2, cycloalkyl, and alkoxy; and wherein each R4 is chosen from hydrogen, alkyl, or alkenyl.

Silicon doping of HZO can be extremely beneficial when between 2.0 to 4.5% of doping is used. The percentage of silicon doping is calculated as follows:

Doping %=Si/(Si+Hf+Zr)*100

To target these concentrations, a low-reactivity Si precursor including but not limited to tris(dimethylalmino) silane (TDMAS) can be used. However, such a precursor may also be known to have poor nucleation, meaning that while doping, it may be possible that the full/uniform coverage of the wafer is not achieved, leading to both inter-wafer and wafer-to-wafer variation. It is proposed to implement a multiple rapid pulsing scheme with TDMAS pulsing, to improve the reproducibility of Si-doping of HZO. By utilizing repeating micropulses of the TDMAS precursor during dopant pulse steps, it is possible to get a good distribution of the surface silicon, despite a poor nucleation. Since the absorption of the Si precursor may be self-limiting as long as operating temperatures are kept below the decomposition temperature of TDMAS, no excessive silicon doping may occur with these multiple rapid pulses, while better nucleation and surface coverage is achieved. That way, an increased wafer-to-wafer reproducibility in addition to inter-wafer silicon doping uniformity in Si-doped HZO is reached.

Additionally, silicon precursors based on water as a co-reactant and water based processes can easily be incorporated into water based HfO2 ALD processes. Although water has many advantages, co-reactants such as O3, O2 and H2O2 can also be used. Examples of such water based silicon precursors are silicon tetraacetate (Si(OOCCH3)4), and Si(R3)4 as defined herein. These precursors leverage the high reactivity with water and in combination with an ALD process for SiO2 would ensure successful incorporation into HfO2 based ALD processes. Various sub cycles of Si or Hf will tune the ratio of these elements in the final films. The deposition temperature can be from 150-450° C. with a more optimized range around 300° C. Additionally, a post deposition anneal may be required to achieve certain film properties such as right phase for either dielectric- or ferro-based films.

In FIG. 2C, a third type of dopant is used to shift the CV curve of an undoped HZO layer 210. By doing so, the shape of the CV curve of the doped HZO layer 240 remains approximately the same, while the peaks shift to higher fields while still maintaining the maximum value of K. In some examples, introducing a low iconic radius dopant such as Ge can create this effect. Doping the HZO layer with an Ge dopant precursor has the effect that the material is forced to adopt a primarily tetragonal phase composition due to the creation of strain and an increase in polar lattice due to a higher electronegativity. This will result in a shift of the maximum peak of the k value to a different region, as well as promoting better linearity. The dopant precursor preferably being a low-reactivity Germanium precursor represented by the general formula Ge(R5)4, wherein each R5 is independently selected from the group consisting of hydrogen, halogen, alkyl, alkenyl, N(R6)2, cycloalkyl, and alkoxy; and wherein each R6 is chosen from hydrogen, alkyl, or alkenyl. However, it should be noted that the present disclosure is not limited to Silicon or Germanium dopants and also other group II-VI elements (e.g. Carbon, Phosphorus, Arsenic, Boron, Indium, Nickel, or Antimony may be used.

When doping a HZO layer with a specific dopant, the k value will be altered which will influence the electric permittivity of the material. The higher the k value, the better the ability of the capacitor to store electric energy in an electrical field. To maximize the charge that a capacitor can hold, the insulator material, being the doped HZO layer, needs to have an as high permittivity as possible, while also having an as high as possible breakdown voltage and an as low as possible loss of frequency. So, depending on the final requirements of the doped HZO layer, a variation in the thickness of the HZO layer, the selected doping elements such as Al, Si, or Ge, a variation in the percentage of doping element used, and environment settings when creating the doped HZO layer can provide for a variation in the reached maximum k value and in the CV characteristics such as a stretched or shifted CV curve.

Typically, a cycle comprises three or more pulses. In some embodiments, at least one pulse involves a self-limiting surface reaction. In some embodiments, all pulses involve a self-limiting surface reaction. In some embodiments, an oxygen reactant pulse is carried out after each hafnium precursor pulse and/or after each zirconium precursor pulse. Using an oxygen reactant pulse after a precursor pulse allows to create thin films on the provided substrate. After the precursor pulse is introduced, it is important to ensure that any excess or unreacted precursor is removed from the reaction chamber before introducing the next reactant. By doing so, unwanted accumulation of precursor molecules is prevented which could otherwise lead to undesired film properties or non-uniformity of the film. Since the precursor pulse also involves chemisorption, where precursor molecules will absorb onto the substrate's surface and react with it, providing an oxygen reactant pulse will help to complete the surface reactions and promote the formation of the desired film on the substrate, assists in removing any residual absorbed precursor molecules and reduce the existence of impurities and defects in the formed film.

In some embodiments, the dopant precursor pulse is carried out after the hafnium precursor pulse, without any intervening oxygen reactant pulse. In the hafnium precursor pulse, the hafnium precursor is provided into the reaction chamber. In the dopant precursor pulse, the dopant compound is provided into the reaction chamber. Hence, a thin film is formed on at least a part of the substrate containing Hafnium and dopant. In some embodiments, the dopant precursor pulse is carried out after the zirconium precursor pulse, without any intervening oxygen reactant pulse. In the zirconium precursor pulse, the zirconium precursor is provided into the reaction chamber. In the dopant precursor pulse, the dopant compound is provided into the reaction chamber. Hence, a thin film is formed on at least a part of the substrate containing at least zirconium and dopant.

It shall be understood that any two steps and/or pulses can be separated by a purge. Thus, in some embodiments, the step of contacting the one or more precursor and/or the step of contacting the dopant compound are separated by a purge. In some embodiments, subsequent cycles are separated by a purge.

In particular embodiments, the method as disclosed herein provides that the one or more cycle, comprising the steps of contacting one or more precursor with at least a part of the substrate and providing the nitrogen compound or another noble gas into the reaction chamber, is quasi free from oxygen, and preferably fully oxygen free. More specifically, the disclosed method provides that the deposition of the HZO film is free from oxygen contaminants, thus lowering the equivalent oxide thickness (EOT) of the dipole and the amount of deposition defects.

In some embodiments, the hafnium precursor pulse, the zirconium precursor pulse, the oxygen reactant pulse and/or the dopant precursor pulse comprises a plurality of micropulses. Micropulsing is a technique used to maintain fine control over thin-film growth, composition and the envisaged properties. Micropulsing involves delivering very short bursts of precursor or reactant gases with precise timing and allows for a better utilization of the precursor material. By delivering small, controlled amounts of precursor, it can be ensured that most of the precursor molecules are chemically absorbed and are able to react with the substrate. It is particularly valuable in processes that require precise atomic or molecular layer deposition and where avoiding excessive precursor exposure is critical for achieving desired film characteristics, as is the case for MIM CAPS having a peak of k at a voltage region of interest.

Non-limiting examples of dopant elements may include Aluminium, Silicon, Nickel, Germanium, Gallium and Carbon.

In particular embodiments, the method as disclosed herein provides for a variation in concentration of the dopant element in the HZO layer. The concentration of the dopant element ranges may be about between 0.50 and 20.0% of the relative dopant element concentration, or about between 2.0 and 18.0% of the relative dopant element concentration, or about between 3.0 and 15.0% of the relative dopant element concentration, or about between 4.0 and 14.0% of the relative dopant element concentration, or about between 4.5 and 12.00% of the relative dopant element concentration or about between 4.75 and 11.50% of the relative dopant element concentration, or about between 6.0 and 11.00% of the relative dopant element concentration, or any appropriate concentration (“about” in this contexts means+/−1.0%).

Alternatively, the molar atomic concentration of the dopant element ranges between 0.50 at. % and 15.0 at. %, more in particular between 0.50 at. % and 10.0 at. %, more in particular between 1.0 at. % and 5.0 at. %, and more in particular between 2.00 at. % and 4.50 at. %. Preferably, the dopant element comprises a molar atomic percentage of less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.5 at. %.

In particular embodiments, a concentration of the dopant element in an HZO layer may be formed with a concentration gradient. Thus, the concentration of the dopant element ranges across an HZO layer from a first interface to a second interface creating a dopant gradient.

In an example, the concentration gradient may vary by any appropriate amount, for example, the gradient may vary from the first interface to the second interface by about between 0.50 and 75.0% of the relative dopant element concentration, or about between 2.0 and 60.0% of the relative dopant element concentration, or about between 3.0 and 50.0% of the relative dopant element concentration, or between about 0.50 and 20.0% of the relative dopant element concentration, or about between 2.0 and 18.0% of the relative dopant element concentration, or about between 3.0 and 15.0% of the relative dopant element concentration, or about between 4.0 and 14.0% of the relative dopant element concentration, or about between 4.5 and 12.00% of the relative dopant element concentration or about between 4.75 and 11.50% of the relative dopant element concentration, or about between 6.0 and 11.00% of the relative dopant element concentration, or any appropriate concentration (“about” in this contexts means+/−1.0%).

In an example, the dopant concentration gradient may be formed by pulsing the one or more dopant precursors into the reaction chamber at a first concentration of dopant elements proximate to a surface or interface of the HZO layer and pulsing the one or more dopant precursors into the reaction chamber at a second concentration of dopant elements proximate to a second surface or interface of the HZO layer wherein the first concentration is different from the second concentration. In one example, the first concentration is higher than the second concentration. In another example, the second concentration is higher than the first concentration.

In an example, the dopant concentration gradient may be formed in the HZO layer by exposing the substrate to an annealing process and driving the dopant elements into the HZO layer. The annealing process may be in addition to forming the dopant concentration gradient by ALD or CVD methods. In an example, a dopant concentration may be deposited near a surface of the HZO layer and a subsequent exposure to an annealing process is used to drive the dopant elements into the HZO film layer.

In an example, the dopant concentration gradient may be formed in the HZO layer by tuning a pulse ratio of one or more dopant precursors versus one or more of, the one or more hafnium precursors, the one or more zirconium precursors, or the oxygen reactant, or a combination thereof, and forming the dopant concentration gradient responsive to the tuning. In an example, the dopant concentration gradient may be formed in the HZO layer by forming a first HZO sub-layer having a first concentration of dopant elements and forming a second HZO sub-layer having a second concentration of the dopant elements, wherein the first concentration of dopant elements is different from the second concentration of dopant elements. In one example, the first concentration is higher than the second concentration. In another example, the second concentration is higher than the first concentration. Additionally, an HZO superlayer comprising a plurality of sublayers comprising differing dopant concentrations may comprise two or more HZO sub-layers each having a different concentration of dopant elements from other HZO sub-layers in the superlayer.

In another example, a flow rate of one or more dopant precursors may be varied in order to form a dopant concentration gradient within an HZO layer.

Alternatively, forming the dopant concentration gradient may comprise tuning a pulse ratio of the one or more dopant precursors versus the one or more hafnium precursors, the one or more zirconium precursors and the oxygen reactant, or a combination thereof, to introduce the dopant precursor at a varied concentration within the HZO layer. In some examples concentration of the dopant element in the HZO layer may range between 0.0 to 20.0% from a first interface to a second interface, wherein the concentration of the dopant element is lowest proximate the first interface and highest proximate the second interface. Alternatively, the concentration of the dopant element may be lowest proximate the first interface and highest proximate the second interface.

In particular embodiments, the dopant element is Al. Further, the dopant precursor is a low-reactivity precursor, preferably a low-reactivity Aluminium precursor represented by the general formula Al(R1)3, wherein each R1 independently selected from the group consisting of hydrogen, halogen, alkyl, alkenyl, N(R2)2, cycloalkyl, and alkoxy; and wherein each R2 is chosen from hydrogen, alkyl, or alkenyl.

In preferred embodiments, each R1 independently selected from the group consisting of hydrogen, halogen, C1-8alkyl, C2-8alkenyl, C3-8cycloalkyl, and C1-8alkoxy; and each R2 is chosen from hydrogen, C1-8alkyl, or C2-8alkenyl.

In more preferred embodiments, each R1 independently selected from the group consisting of hydrogen, halogen, C1-4alkyl, C2-4alkenyl, C3-8cycloalkyl, and C1-4alkoxy; and each R2 is chosen from hydrogen, C1-4alkyl, or C2-4alkenyl.

In particular embodiments, said Aluminium precursor is selected from the list consisting of aluminium hydride (AlH3), aluminium trifluoride (AlF3), aluminium trichloride (AlCl3), aluminium tribromide (AlBr3), aluminium triiodide (AlI3), trimethylaluminium (Al(CH3)3), triethylaluminium (Al(C2H5)3, tri (isopropyl)aluminium (Al(iPr)3), tetra-n-butylaluminium (Al(C4H9)3), tetra-t-butylaluminium (Al(OtBu)3), aluminium methoxide (Al(OCH3)3), aluminium ethoxide (Al(OC2H5)3), aluminium isopropoxide (Al(OiPr)3), aluminium n-butoxide (Al(OC4H9)3), and aluminium t-butoxide (Al(OtBu)3).

In particular embodiments, the dopant element is Si. Further, the dopant precursor is a low-reactivity precursor, said dopant precursor preferably being a low-reactivity Silicon precursor selected from the list consisting of silicon tetraacetate (Si(OOCCH3)4), and Si(R3)4, wherein each R3 is independently selected from the group consisting of hydrogen, halogen, alkyl, alkenyl, N(R4)2, cycloalkyl, and alkoxy; and wherein each R4 is chosen from hydrogen, alkyl, or alkenyl. In preferred embodiments, each R3 is independently selected from the group consisting of hydrogen, halogen, C1-8alkyl, C2-8alkenyl, C3-8cycloalkyl, and C1-8alkoxy; and each R4 is chosen from hydrogen, C1-8alkyl, or C2-8alkenyl.

In more preferred embodiments, each R3 is independently selected from the group consisting of hydrogen, halogen, C1-4alkyl, C2-4alkenyl, C3-8cycloalkyl, and C1-4alkoxy; and each R4 is chosen from hydrogen, C1-4alkyl, or C2-4alkenyl.

In particular embodiments, said silicon precursor is selected from the list consisting of silane (SiH4), silicon tetrafluoride (SiF4), silicon tetrachloride (SiCl4), silicon tetrabromide (SiBr4), silicon tetraiodide (SiI4), tetramethylsilane (Si(CH3)4), tetraethylsilane (Si(C2H5)4, tetra(isopropyl) silane (Si(iPr)4), tetra-n-butylsilane (Si(C4H9)4), tetra-t-butylysilane (Si(OtBu)4), tetramethoxysilane (Si(OCH3)4), tetraethoxysilane (Si(OC2H5)4), tetra(isopropoxy) silane (Si(OiPr)4), tetra-n-butoxysilane (Si(OC4H9)4), tetra-t-butoxysilane (Si(OtBu)4), and tris(dimethylamino) silane (Si(N[CH3]2)3).

In particular embodiments, the dopant element is Ge. Further, the dopant precursor is a low-reactivity precursor, preferably a low-reactivity Germanium precursor represented by the general formula Ge(R5)4, wherein each R5 is independently selected from the group consisting of hydrogen, halogen, alkyl, alkenyl, N(R6)2, cycloalkyl, and alkoxy; and wherein each R6 is chosen from hydrogen, alkyl, or alkenyl.

In preferred embodiments, each R5 is independently selected from the group consisting of hydrogen, halogen, C1-8alkyl, C2-8alkenyl, C3-8cycloalkyl, and C1-8alkoxy; and each R6 is chosen from hydrogen, C1-8alkyl, or C2-8alkenyl.

In more preferred embodiments, each R5 is independently selected from the group consisting of hydrogen, halogen, C1-4alkyl, C2-4alkenyl, C3-8cycloalkyl, and C1-4alkoxy; and each R6 is chosen from hydrogen, C1-4alkyl, or C2-4alkenyl.

In particular embodiments, said Germanium precursor is selected from the list consisting of germane (GeH4), germanium tetrafluoride (GeF4), germanium tetrachloride (GeCl4), germanium tetrabromide (GeBr4), germanium tetraiodide (GeI4), tetramethylgermanium (Ge(CH3)4), tetraethylgermanium (Ge(C2H5)4, tetra(isopropyl)germanium (Ge(iPr)4), tetra-n-butylgermanium (Ge(C4H9)4), tetra-t-butylgermanium (Ge(OtBu)4), tetramethoxygermanium (Ge(OCH3)4), tetraethoxygermanium (Ge(OC2H5)4), tetra(isopropoxy)germanium (Ge(OC3H7)4), tetra-n-butoxygermanium (Ge(OC4H9)4), tetra-t-butoxygermanium (Ge(OtBu)4), and tris(dimethylamino)germanium (Ge(N[CH3]2)3).

In some examples, HZO layers doped with Ge, Si and/or Al can be particularly advantageous for to force the layer to adopt a primarily tetragonal phase composition thus shifting the maximum k peaks to a region voltage region of interest, while promoting a better linearity.

A low-reactivity precursor is a chemical compound that has limited reactivity under specific conditions. In thin-film deposition techniques, such as ALD, a low-reactivity precursor is a precursor compound that does not readily undergo chemical reactions or decomposition at low temperatures or under the conditions of the deposition process.

In the described methods, the goal is to deposit thin films in a controlled and uniform manner. Using a low-reactivity precursor may be desirable because such a precursor may allow for precise control of the film growth without premature reactions or decomposition on the substrate surface.

Additionally, low-reactivity precursors are especially useful when the deposition process needs to occur at a temperature which is compatible with the substrate and the desired film properties. Since the reactivity of low-reactivity precursors can be adjusted by varying the process conditions such as temperature, pressure and exposure time, small variations may alter the reactivity of the low-reactivity precursor and thus accommodate for a specific deposition process, material and desired film characteristics.

In particular embodiments, the method as disclosed herein provides that the hafnium precursor is represented by the following general formula (I),

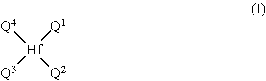

wherein Q1, Q2, Q3, Q4 are each independently chosen from the group consisting of halogen, alkyl, alkenyl, N(R7)2, alkoxy, heteroalkyl, cycloalkyl, aryl, and cyclopentadienyl; and wherein each R7 is independently hydrogen, alkyl, or alkenyl.

In some embodiments, the present disclosure provides that Q1, Q2, Q3, Q4 are each independently chosen from the group consisting of halogen, C1-8alkyl, C2-8alkenyl, N(R7)2, C1-8alkoxy, heteroC1-8alkyl, C3-8cycloalkyl, C6-10aryl, and cyclopentadienyl; wherein each R7 is independently hydrogen, C1-8alkyl, or C2-8alkenyl.

In some embodiments, the present disclosure provides that Q1, Q2, Q3, Q4 are each independently chosen from the group consisting of halogen, C1-4alkyl, C2-4alkenyl, N(R7)2, C1-4alkoxy, heteroC1-4alkyl, C3-8cycloalkyl, C6-10aryl, and cyclopentadienyl; wherein each R7 is independently hydrogen, C1-4alkyl, or C2-4alkenyl.

In particular embodiments, the method as disclosed herein provides that the hafnium precursor is chosen from the group consisting of HfCl4, HfBr4, HfI4, HfMe4, HfEt4, Hf(nPr)4, Hf(iPr)4, Hf(nBu)4, Hf(tBu)4, Hf(NMe2)4, Hf(NEt2)4, Hf[MeEtN]4, HfCp[(NMe2)3], Hf(OMe)4, Hf(OEt)4, Hf(OnPr)4, Hf(OiPr)4, Hf(OnBu)4, Hf(OtBu)4, Hf[(CpMe)2][OMe][Me], Hf[(CpMe)2][(Me)2], Tetrakis(1-methoxy-2-methyl-2-propoxy) hafnium (Hf(mmp)4).

Using a hafnium precursor when depositing thin films on a substrate commonly results in hafnium based materials having a high dielectric constant k compared to traditional silicon dioxide (SiO2), enabling better control of gate leakage and improved device performance.

In particular embodiments, the method as disclosed herein provides that the zirconium precursor is represented by the following general formula (II),

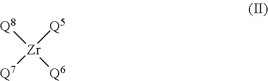

wherein Q5, Q6, Q7, Q8 are each independently chosen from the group consisting of halogen, alkyl, alkenyl, N(R8)2, alkoxy, heteroalkyl, cycloalkyl, aryl, and cyclopentadienyl; wherein each R8 is independently hydrogen, alkyl, or alkenyl.

In some embodiments, the present disclosure provides that Q5, Q6, Q7, Q8 are each independently chosen from the group consisting of halogen, C1-8alkyl, C2-8alkenyl, N(R8)2, C1-8alkoxy, heteroC1-8alkyl, C3-8cycloalkyl, C6-10aryl, and cyclopentadienyl; wherein each R8 is independently hydrogen, C1-8alkyl, or C2-8alkenyl.

In some embodiments, the present disclosure provides that Q5, Q6, Q7, Q8 are each independently chosen from the group consisting of halogen, C1-4alkyl, C2-4alkenyl, N(R8)2, C1-4alkoxy, heteroC1-4alkyl, C3-8cycloalkyl, C6-10aryl, and cyclopentadienyl; wherein each R8 is independently hydrogen, C1-4alkyl, or C2-4alkenyl.

In particular embodiments, the method as disclosed herein provides that the zirconium precursor is chosen from the group consisting of ZrCl4, ZrBr4, ZrI4, ZrMe4, ZrEt4, Zr(nPr)4, Zr(iPr)4, Zr(nBu)4, Zr(tBu)4, Zr(NMe2)4, Zr(NEt2)4, Zr[MeEtN]4, ZrCp[(NMe2)3], Zr(OMe)4, Zr(OEt)4, Zr(OnPr)4, Zr(OiPr)4, Zr(OnBu)4, Zr(OtBu)4, Zr[(CpMe)2][OMe][Me], Zr[(CpMe)2][(Me)2], Tetrakis(1-methoxy-2-methyl-2-propoxy)zirconium (Zr(mmp)4).

Using a zirconium precursor when depositing thin films on a substrate commonly results in zirconium based materials having a high dielectric constant k compared to traditional silicon dioxide (SiO2), which helps to maintain gate capacitance while reducing gate oxide thickness in scaled-down applications. Further, using a zirconium precursor creates a barrier coating in microelectronics to prevent diffusion of metals into the dielectric layer, thus enhancing the reliability and performance of interconnect structures.

In particular embodiments, the method as disclosed herein provides that the decomposition temperature of the dopant precursor is higher compared to the operating temperature to form the doped hafnium zirconium oxide (HZO) layer. The decomposition temperature refers to the temperature at which the precursor molecule breaks down or undergoes chemical reactions that lead to the deposition of the dopant material on the substrate surface. The decomposition temperature of a dopant precursor is a critical parameter when using it in thin-film deposition processes like ALD. If the precursor decomposes at a temperature significantly lower than the process temperature, premature decomposition might occur in the gas phase, leading to the deposition of unintended reaction by-products and poor film quality. Further, precursor decomposition at the proper temperature ensures that the dopant material is deposited in its desired form without incorporating impurities or producing defective films. However, if the precursor decomposes at too high a temperature, it might not fully decompose on the substrate surface, leading to incomplete film growth and wasted precursor.

Therefore, in particular embodiments, the method as disclosed herein provides that the operating temperature to form the doped HZO layer is between 150° C. and 450° C., preferably between 250° C. and 350° C., more preferably around 300° C.

In particular embodiments, the method as disclosed herein further provides that the substrate comprises a Metal Oxide (MO) surface layer, and/or wherein said method further comprises the step of forming a Metal Oxide (MO) top layer on the doped HZO layer, thereby forming a layered doped HZO structure. Further, the MO surface layer and/or the MO top layer is in direct contact with the doped HZO layer. The metal oxide is preferably TiO2.

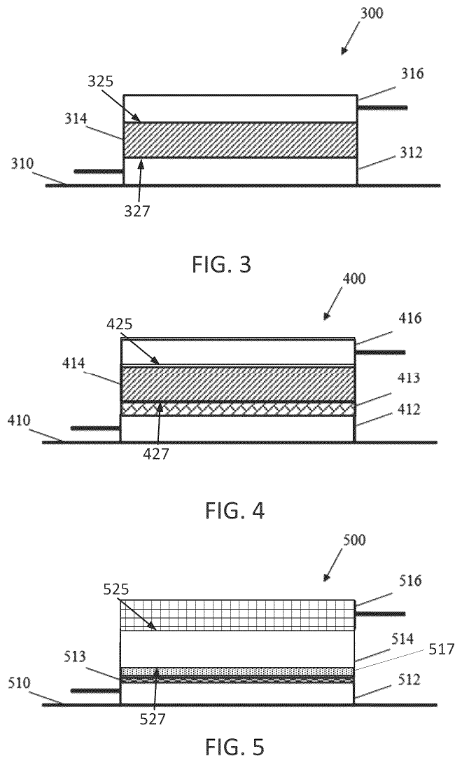

FIG. 3 illustrates an exemplary MIM capacitor 300 of the disclosure, consisting of two metal layers or electrodes 312, 316, separated by an insulator layer or dielectric 314 and a substrate 310 holding the two metal layers 312, 316 and insulator layer 314. The insulator layer 314 is a doped HZO layer formed by the method as described in relation to FIG. 1.

Depending on the requirements of the specific MIM capacitor 300, a different dopant can be used to create the insulator or doped HZO layer 314, thus resulting in a MIM capacitor having specifically designed specifications. In some examples, HZO insulator layer 314 may comprise a dopant concentration gradient. Such a dopant concentration gradient, as described hereinabove, may extend from a first interface 325 to a second interface 327 wherein the concentration of dopant may increase from first interface 325 to second interface 327, or may decrease from first interface 325 to second interface 327.

In particular embodiments, the method as disclosed herein further comprising the step of providing a seed layer prior to forming the doped HZO layer, the seed layer may comprise a ZrO2 seed layer. The seed layer serves as a foundation or nucleation site for the subsequent deposition of the doped HZO layer 314. Such a seed layer creates a more favorable surface for the nucleation and growth of the doped HZO layer 314 and provides sites for the HZO precursor molecules to attach and react. This will lead to a more uniform and controlled film growth. Additionally, a seed layer may enhance the adhesion between the doped HZO layer 314 and the substrate 310, thus reducing the risk of delamination or peeling. In cases where the substrate's topography or surface is such that a conformal HZO deposition is challenging, the seed layer will create a smoother and more uniform surface, enabling better conformal coverage of the subsequently deposited HZO layer. In some cases, the material of the substrate may react with the HZO precursors, leading to undesirable reactions or phase changes. The seed layer will act in these cases as a buffer, preventing direct contact between the substrate and the doped HZO precursor. It shall be understood that when a seed layer is deposited on the substrate, intermixing of those layer's constituent components may occur to some extent.

For example, when a ZrO2 containing seed layer is deposited on a substrate, at least one of the zirconium or oxygen may be incorporated into the substrate layer, for example by means of diffusion, surface segregation, or another process. In some embodiments, such intermixing can result in the formation of an interlayer containing both components of each layer.

In particular situations, for instance when a high dielectric constant value k of above 35 between about −2 and −3 MV/cm is needed, such a deposition of a seed layer prior to the doped HZO layer 314 deposition can be beneficial to reach these requirements and to reduce the above identified issues which may occur when not using such a seed layer. FIG. 4 illustrates an exemplary MIM capacitor 400 having such a seed layer 413 and a doped HZO layer 414 instead of only the doped HZO layer 314 as illustrated in FIG. 3. MIM capacitor 400 may comprise two metal layers or electrodes 412, 416, and a substrate 410. In an exemplary embodiment, ZrO2 is used as a seed layer 413 prior to the doped HZO layer 414 deposition. The seed layer 413 aids in promoting tetragonal phase and induces strain in the HZO films, thus boosting the value K. This in combination with a precise selection of dopants can help achieve high k values at a specific voltage range such as e.g. between −2 and −3 MV/cm. Such a combination can result in an increase of 6% to 10% of the k value. In some examples, HZO layer 414 may comprise a dopant concentration gradient. Such a dopant concentration gradient, as described hereinabove, may extend from a first interface 425 to a second interface 427 wherein the concentration of dopant may increase from first interface 425 to second interface 427, or may decrease from first interface 425 to second interface 427.

In the context of MIM and MOS capacitors, a symmetric CV characteristic is desirable. The symmetry in the CV characteristic means that the capacitance remains constant over a range of applied voltages, which is a desirable property for many applications.

Symmetricity of CV curves also provides a larger tolerance to the device structure and integration scheme and may make operation independent of the polarity of bias voltage. However, many higher-k materials (e.g., beyond HfOx having a k value of about 20-24), exhibit highly asymmetric CV characteristics due to polar atomic domains that are ferroelectric/antiferroelectric in nature. These domains can experience different polarization fields depending on the interface and polarity of the applied voltage, adding to the magnitude of asymmetry. The most common reason for asymmetry is the presence of interface defects that alter the polarization fields for the ferroelectric/antiferroelectric domains. In some cases, unintentional oxidation of a TiN electrode can result in a TiON interface that modifies the polarization fields.

Deposition of a ZrO2 seed layer 413 with the doped HZO layer 414 deposition can be beneficial to symmetrize the CV characteristics of the doped HZO layer 414 while increasing the dielectric constant and reducing leakage current. Adding the ZrO2 seed layer 413 seems to balance the polarization fields, resulting in better symmetry. In some cases, adding a ZrO2 seed layer can reduce the CV asymmetry from 16% to 6%.

In an example, deposition of a ZrO2 seed layer 413, in tandem with the doped HZO layer 414 and a titanium oxide (TiO) liner (see for example TiO liner 513 FIG. 5), has been shown to enhance the symmetry of the CV characteristics further. While a TiO liner may be disposed proximate to a top electrode 416 or a bottom electrode 412 comprising TiN, placement of the TiO liner in proximity to the bottom TiN electrode (BE) improves the symmetry of the CV curve even more. Without being bound by theory, adding a TiO liner at the BE may mitigate the different polarization field caused by a TiON—HZO interface, balancing the CV curve asymmetry. The TiON—HZO interface may result because the BE 412 experiences the max thermal budget and hence oxidizes more compared to a top electrode (TE) 416.

This method not only increases the dielectric constant and reduces leakage current but also balances the polarization fields more effectively, leading to improved symmetry. Notably, the use of TiCl4 and H2O for the deposition of the TiO liner layer, instead of first depositing TiN and then converting it to TiO, is advantageous. This approach avoids the introduction of TiON, which can create a TiON—HZO interface that alters the polarization fields and contributes to CV curve asymmetry. In practice, this optimized layering can reduce CV asymmetry dramatically, from 16% down to as low as 2.5%, by mitigating the disparate polarization fields at the bottom electrode, which experiences the maximum thermal budget and is prone to higher rates of oxidation compared to the top electrode.

FIG. 5 illustrates such an exemplary MIM capacitor 500 having a bottom electrode (BE) layer 512 comprising TiN which is deposited on the substrate 510. A thin liner layer of TiO2 513 is deposited on BE layer 512 by ALD using TiCl4 and H2O. A seed layer 517 (as described above, also see layer 413 illustrated in FIG. 4) may be formed over liner layer of TiO2 513. A dielectric layer 514 having a high dielectric constant is then deposited over seed layer 513 using metal-organic precursors. Such a dielectric layer 514 may comprise an HZO layer doped with Si, Al, and/or Ge. In some examples, the dopants may form a gradient. In some examples, the lower dopant concentration may be nearest an interface to enable low leakage. In other examples, dielectric layer 514 may comprise a different material having a high dielectric constant (e.g., having a k value greater than 20). Such materials may comprise, for example, zirconium oxide (ZrOx), hafnium oxide (HfOx), or Al-doped HfOx, or the like or a combination thereof. Finally, a top TiN layer 516 is deposited by ALD resulting in a MIM capacitor 500. In an example, MIM capacitor 500 may have a more symmetrical CV curve compared to a MIM capacitor 500 without a doped dielectric layer 514 and both a liner layer of TiO2 513 and a seed layer 517.

In some examples, dielectric layer 514 comprising HZO may comprise a dopant concentration gradient. Such a dopant concentration gradient, as described hereinabove, may extend from a first interface 525 to a second interface 527 wherein the concentration of dopant may increase from first interface 525 to second interface 527, or may decrease from first interface 525 to second interface 527.

In an example, the doped HZO dielectric layer 514 increases the dielectric constant value (K) of the doped HZO dielectric layer 514 with respect to an HZO layer without the dopant or with respect to HfO which is the industry standard.

In another example, doped HZO dielectric layer 514 decreases leakage with respect to an HZO layer without dopant.

In another example, doped HZO dielectric layer 514 increases the dielectric constant value (K) and decreases the leakage with respect to an HZO layer without the dopant.

For current and future gate oxide technology nodes that span FinFETs, gate-all-around (GAAs) and complementary field-effect-transistors (CFETs), there is a need for high dielectric constant (k) gate oxide to reduce equivalent oxide thickness (EOT) further when compared to the currently adopted HfO. EOT is the thickness of a silicon oxide film that provides the same electrical performance as that of a high-K (high dielectric constant) material being used. The term is often used when describing field effect transistors, which rely on an electrically insulating pad of material between a gate and a doped semiconducting region. Device performance tends to improve by reducing the thickness of a silicon oxide however, leakage current becomes more problematic as thicknesses decrease. New materials are needed with lower EOT so they can retain an appropriate gate oxide thickness to prevent leakage current while also maintaining performance speed.

A doped HZO layer as disclosed herein is a good alternative where high CV non-linearities due to interplay of Ferroelectric (FE) and anti-Ferroelectric (AFE) behavior in these films are reduced by addition of the above disclosed dopants. The leakage in such films when scaled down (≤45 A) is very high and is expected to be even worse for 15-20 angstrom films

Existing approaches to reduce leakage in these films utilize post deposition anneal (PDA), but the process window is very small, difficult to control precisely and present integration issues.

Doping with relatively non-polar ions of small ionic radius and high electronegativity can help reduce the non-linearities in CV and leakage if the mixture of polar and non-polar domains are optimized. Doping via ALD allows for more precise control when compared to anneal processes.

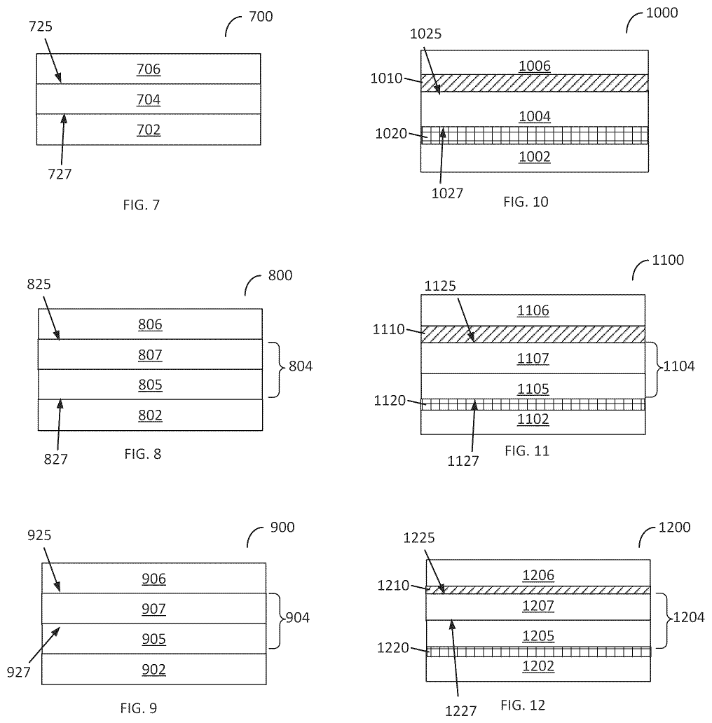

FIG. 7 illustrates such an exemplary device 700 comprising a gate oxide appropriate for use in, for example, in a metal-oxide-semiconductor field effect transistor (MOSFET) including but not limited to GAA, CFET and/or finFET. In an example, device 700 comprises an interfacial layer 702 comprising any appropriate material known to those of skill in the art, such as for example, silicon oxide (SiOx), a doped high-k layer 704 comprising HZO doped according to methods disclose herein above and an electrode layer 706 comprising any appropriate material known to those of skill in the art, such as for example, titanium nitride (TiN).

In an example, doped high-k layer 704 may be doped by a variety of methods including ALD and/or by annealing. In some examples, doped high-k layer 704 may comprise a dopant concentration gradient. Such a dopant concentration gradient, as described hereinabove, may extend from a first interface 725 to a second interface 727 wherein the concentration of dopant may increase from first interface 725 to second interface 727, or may decrease from first interface 725 to second interface 727.

FIG. 8 illustrates a device 800 comprising a gate oxide appropriate for use in, for example, in a metal-oxide-semiconductor field effect transistor (MOSFET) including but not limited to GAA, CFET and/or finFET. In an example, device 800 comprises an interfacial layer 802 comprising any appropriate material known to those of skill in the art, such as for example, silicon oxide (SiOx), a high-k nanolaminate layer 804 comprising a first nanolaminate sub-layer 805 and a second nanolaminate sublayer 807 and an electrode layer 806 comprising any appropriate material known to those of skill in the art, such as for example, titanium nitride (TiN). Nanolaminar films that are Hf rich at the bottom near interfacial layer and Zr rich at the top near the electrode layer may reduce leakage better than mixed HZO films. In an example, first nanolaminate sub-layer 805 may comprise HZO that is Hf rich (“rich” herein is defined as comprising more than 50% atomic percentage of Hf). In an example, second nanolaminate sublayer 807 may comprise HZO that is Zr rich (“rich” herein is defined as comprising more than 50% atomic percentage of Zr). In an example, a high-k nanolaminate layer 804 may further comprise HZO doped according to methods disclose herein above and/or may be doped by a variety of methods including ALD and/or by annealing. In some examples, doped high-k nanolaminate layer 804 may comprise a dopant concentration gradient. Such a dopant concentration gradient, as described hereinabove, may extend from a first interface 825 to a second interface 827 extending across the high-k nanolaminate layer 804 wherein the concentration of dopant may increase from first interface 825 to second interface 827, or may decrease from first interface 825 to second interface 827.

FIG. 9 illustrates a device 900 comprising a gate oxide appropriate for use in, for example, in a metal-oxide-semiconductor field effect transistor (MOSFET) including but not limited to GAA, CFET and/or finFET. In an example, device 900 comprises an interfacial layer 902 comprising any appropriate material known to those of skill in the art, such as for example, silicon oxide (SiOx), a high-k nanolaminate layer 904 comprising a first nanolaminate sub-layer 905 and a second nanolaminate sublayer 907 and an electrode layer 906 comprising any appropriate material known to those of skill in the art, such as for example, titanium nitride (TiN).

In an example, first nanolaminate sub-layer 905 may comprise HZO that is Zr rich (“rich” herein is defined as comprising more than 50% atomic percentage of Zr).

In an example, second nanolaminate sublayer 907 may comprise HZO that is Hf rich (“rich” herein is defined as comprising more than 50% atomic percentage of Hf).

In an example, a high-k nanolaminate layer 904 may further comprise HZO doped according to methods disclose herein above and/or may be doped by a variety of methods including ALD and/or by annealing. In some examples, high-k nanolaminate layer 904 may only be doped in a portion of the sublayers. For example, second nanolaminate sublayer 907 is doped while first nanolaminate sublayer 905 is not doped. Second nanolaminate sublayer 907 may comprise a dopant concentration gradient. Such a dopant concentration gradient, as described hereinabove, may extend from a first interface 925 to a second interface 927 wherein the concentration of dopant may increase from first interface 925 to second interface 927, or may decrease from first interface 925 to second interface 927.

FIG. 10 illustrates a device 1000 comprising a gate oxide appropriate for use in, for example, in a metal-oxide-semiconductor field effect transistor (MOSFET) including but not limited to GAA, CFET and/or finFET. In an example, device 1000 comprises an interfacial layer 1002 comprising any appropriate material known to those of skill in the art, such as for example, silicon oxide (SiOx), a ZrO2 seed layer 1020 formed on the interfacial layer 1002 according to methods disclosed herein, a doped high-k layer 1004 comprising HZO doped according to methods disclose herein disposed on seed layer 1020, a titanium oxide liner 1010 formed on doped high-k layer 1004 according to methods disclose herein and an electrode layer 1006 comprising any appropriate material known to those of skill in the art, such as for example, titanium nitride (TiN).

In an example, doped high-k layer 1004 may be doped by a variety of methods including ALD and/or by annealing. In some examples, doped high-k layer 1004 may comprise a dopant concentration gradient. Such a dopant concentration gradient, as described hereinabove, may extend from a first interface 1025 to a second interface 1027 wherein the concentration of dopant may increase from first interface 1025 to second interface 1027, or may decrease from first interface 1025 to second interface 1027.

In an example, during deposition ZrO2 seed layer 1020 may be formed prior to forming the doped high-k layer 1004.

In an example, the titanium oxide liner 1010 may be deposited by ALD using TiCl4 and H2O. The ZrO2 seed layer 1020 may be formed over liner layer of titanium oxide, in a different stack, for example where a BE is formed below the HZO layer.

FIG. 11 illustrates a device 1100 comprising a gate oxide appropriate for use in, for example, in a metal-oxide-semiconductor field effect transistor (MOSFET) including but not limited to GAA, CFET and/or finFET. In an example, device 1100 comprises an interfacial layer 1102 comprising any appropriate material known to those of skill in the art, such as for example, silicon oxide (SiOx), a ZrO2 seed layer 1120 formed on the interfacial layer 1102 according to methods disclosed herein, a high-k nanolaminate layer 1104 comprising a first nanolaminate sub-layer 1105 and a second nanolaminate sublayer 1107, a TiO liner 1110 formed on high-k nanolaminate layer 1104 according to methods disclose herein and an electrode layer 1106 comprising any appropriate material known to those of skill in the art, such as for example, titanium nitride (TiN). Nanolaminar films that are Hf rich at the bottom near interfacial layer 1102 and Zr rich at the top near the electrode layer 1106 may reduce leakage better than mixed HZO films. In an example, first nanolaminate sub-layer 1105 may comprise HZO that is Hf rich (“rich” herein is defined as comprising more than 50% atomic percentage of Hf). In an example, second nanolaminate sublayer 1107 may comprise HZO that is Zr rich (“rich” herein is defined as comprising more than 50% atomic percentage of Zr). In an example, a high-k nanolaminate layer 1104 may further comprise HZO doped according to methods disclose herein above and/or may be doped by a variety of methods including ALD and/or by annealing. In some examples, doped high-k nanolaminate layer 1104 may comprise a dopant concentration gradient. Such a dopant concentration gradient, as described hereinabove, may extend from a first interface 1125 to a second interface 1127 extending across the high-k nanolaminate layer 1104 wherein the concentration of dopant may increase from first interface 1125 to second interface 1127, or may decrease from first interface 1125 to second interface 1127.

FIG. 12 illustrates a device 1200 comprising a gate oxide appropriate for use in, for example, in a metal-oxide-semiconductor field effect transistor (MOSFET) including but not limited to GAA, CFET and/or finFET. In an example, device 1200 comprises an interfacial layer 1202 comprising any appropriate material known to those of skill in the art, such as for example, silicon oxide (SiOx), a ZrO2 seed layer 1220 formed on the interfacial layer 1202 according to methods disclosed herein, a high-k nanolaminate layer 1204 comprising a first nanolaminate sub-layer 1205 and a second nanolaminate sublayer 1207, a TiO liner 1210 formed on high-k nanolaminate layer 1204 according to methods disclosed herein and an electrode layer 1206 comprising any appropriate material known to those of skill in the art, such as for example, titanium nitride (TiN).

In an example, first nanolaminate sub-layer 1205 may comprise HZO that is Zr rich (“rich” herein is defined as comprising more than 50% atomic percentage of Zr).

In an example, second nanolaminate sublayer 1207 may comprise HZO that is Hf rich (“rich” herein is defined as comprising more than 50% atomic percentage of Hf).

In an example, a high-k nanolaminate layer 1204 may further comprise HZO doped according to methods disclose herein above and/or may be doped by a variety of methods including ALD and/or by annealing. In some examples, high-k nanolaminate layer 1204 may only be doped in a portion of the sublayers. For example, second nanolaminate sublayer 1207 is doped while first nanolaminate sublayer 1205 is not doped. Second nanolaminate sublayer 1207 may comprise a dopant concentration gradient. Such a dopant concentration gradient, as described hereinabove, may extend from a first interface 1225 to a second interface 1227 wherein the concentration of dopant may increase from first interface 1225 to second interface 1227, or may decrease from first interface 1225 to second interface 1227.

FIGS. 10-12 illustrate a variety of devices comprising a TiO line and seed layer. For simplicity these devices are shown having both, however, it is contemplated that the illustrated devices may have either only a TiO liner or seed layer and claimed subject matter is not limited in this regard.

FIGS. 8-9, 11-12 illustrate a variety of devices comprising nanolaminate HZO films. For simplicity two sublayers are illustrated in the FIGs, however, any appropriate number of sub-layers may be formed and claimed subject matter is not limited in this regard. Furthermore, the HZO nanolaminate films described below may be substituted into any appropriate device, especially where high-k materials may be used (e.g., devices 300, 400, 500, see FIGS. 3, 4, 5) and claimed subject matter is not limited in this regard.

The above disclosed nanolaminate HZO structures (e.g., nanolaminate layer 804, nanolaminate layer 904, nanolaminate layer 1104, nanolaminate layer 1204, see FIGS. 8, 9, 11, 12) may be deposited by methods disclosed herein (see, for example, FIG. 1). In an example, forming a nanolaminate structure on the substrate may comprise forming a first hafnium zirconium oxide (HZO) sub-layer and a second hafnium zirconium oxide (HZO) sub-layer, by a cyclic process, may comprise the following operations a) pulsing one or more hafnium precursors into the reaction chamber, wherein at least a part of the substrate is contacted with the one or more hafnium precursors; b) pulsing one or more zirconium precursors into the reaction chamber, wherein at least a part of the substrate is contacted with the one or more zirconium precursors; c) pulsing an oxygen reactant into the reaction chamber, wherein at least a part of the substrate is contacted with the one or more oxygen reactants; and d) purging the reaction chamber and e) repeating one or more of operations a), b), c), or d), or a combination thereof, in any order, until a first HZO sub-layer having a first predetermined thickness and the second HZO sub-layer comprising a second predetermined thickness are deposited on the substrate and wherein the first HZO sub-layer and the second HZO sub-layer comprise different concentrations of Hf and different concentrations of Zr.

In some examples, the first sublayer is Hf rich and the second sublayer is Zr rich (“rich” means the layer has greater than 50% atomic percent concentration). In some examples, the first sublayer is Zr rich and the second sublayer is Hf rich (“rich” means the layer has greater than 50% atomic percent concentration). In this example, varying a flow rate or pulse ratio of the one or more hafnium precursors, the one or more zirconium precursors and/or the oxygen reactant, or a combination thereof can provide a variance in the concentrations of precursor thus enabling deposition of a first concentration of Hf in the first HZO sub-layer and deposition of a second concentration of Hf in the second HZO sub-layer. In some examples, the first concentration of Hf is greater than the second concentration of Hf. In some examples, the first concentration of Zr is less than the second concentration of Zr.

In another example, varying a flow rate of the one or more zirconium precursors or varying a pulse ratio of the one or more hafnium precursors, the one or more zirconium precursors and the oxygen reactant, or a combination thereof provides a first concentration of Zr in the first HZO sub-layer and deposit a second concentration of Zr in the second HZO sub-layer.

In some examples, doping according to a methods disclosed herein one or more HZO sub-layer may proceed responsive to k) pulsing one or more dopant precursors into the reaction chamber, wherein at least a part of the substrate is contacted with the one or more dopant precursors.

Moreover, forming a dopant concentration gradient within the nanolaminate structure may proceed responsive to varying a flow rate of the one or more dopant precursors or tuning a pulse ratio of the one or more dopant precursors versus one or more of, the one or more hafnium precursors, the one or more zirconium precursors, or the oxygen reactant, or a combination thereof.

Forming the dopant concentration gradient within the nanolaminate structure further comprises imparting a first concentration of dopant elements into the first HZO sub-layer and imparting a second concentration of dopant elements into the second HZO sub-layer, wherein the first concentration of dopant elements is different from the second concentration of dopant elements.

The concentration of the dopant element in the doped HZO nanolaminate structure ranges between 0.0 to 15.0% from a first interface to a second interface, wherein the concentration of the dopant element is lowest proximate the first interface and highest proximate the second interface.

The dopant precursor comprises a dopant element characterized by having three or four valence electrons and an atomic radius which is less than the atomic radius of an Hf or Zr element of the HZO layer.

Typically, the doped HZO layers are formed on a substrate which is first introduced into the reaction chamber prior to the formation of the doped HZO layer. Non-limiting examples of a substrate may include a sheet or a flexible material. Substrates may also comprise carriers or sheets upon which substrates are mounted.

In particular embodiments, the method as disclosed herein provides that the doped HZO layer or the layered doped HZO structure is formed without any intervening vacuum break. Intervening vacuum breaks can introduce process pauses, which are not desirable in high-throughput manufacturing scenarios, thus leading to a more continuous and streamlined process. Also, deposition techniques, such as ALD thrive on continuous and controlled precursor exposure. Interrupting the process with vacuum breaks may introduce variations in film growth and quality, and may also increase the contamination risk since intervening vacuum breaks can potentially introduce contaminants or oxygen, particularly if the vacuum chamber is not thoroughly purged during the break. Therefore, continuous deposition without introducing intervening vacuum breaks reduces the risk of introducing impurities in the doped HZO layer.

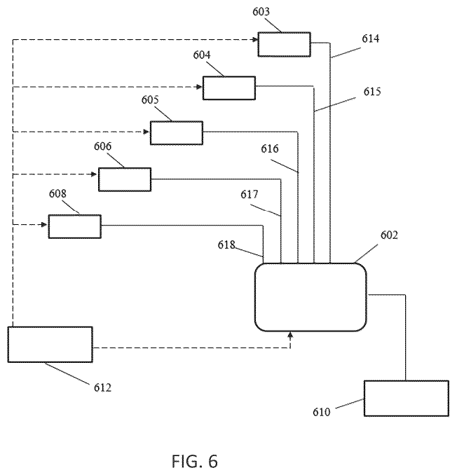

In some preferred embodiments, the present disclosure relates to a system, wherein the system is configured to perform the method as disclosed herein. FIG. 6 illustrates such a system 600 in accordance with exemplary embodiments of the disclosure. In the illustrated example, the system 600 can be used to perform a method as described herein and/or form a structure or device portion as described herein.

In the illustrated example, the system 600 includes one or more reaction chambers 602, a hafnium precursor source 603, a zirconium precursor source 604, an oxygen reactant source 605, a dopant precursor source 606, a purge gas source 608, an exhaust 610, and a controller 612. The reaction chamber 602 can include any suitable reaction chamber, such as an ALD reaction chamber.

The precursor sources 603, 604 can include a vessel and one or more precursors as described herein-alone or mixed with one or more carrier (e.g., inert) gases. The dopant precursor source 606 can include a vessel and one or more dopant compounds as described herein-alone or mixed with one or more carrier gases. The purge gas source 608 can include one or more inert gases such as N2 or a noble gas, as described herein. The system 600 can include any suitable number of sources. The sources 603-608 can be coupled to reaction chamber 602 via lines 614-618, which can each include flow controllers, valves, heaters, and the like. The exhaust 610 can include one or more vacuum pumps.

The controller 612 includes electronic circuitry and software to selectively operate valves, manifolds, heaters, pumps and other components included in the system 600. Such circuitry and components operate to introduce precursors, reactants, and purge gases from the respective sources 604-608. The controller 612 can control timing of gas pulse sequences, temperature of the substrate and/or reaction chamber, pressure within the reaction chamber, and various other operations to provide proper operation of the system 600. The controller 612 can include control software to electrically or pneumatically control valves to control flow of precursors, reactants (i.e. nitrogen compounds and/or oxygen compounds) and purge gases into and out of the reaction chamber 602. The controller 612 can include modules such as a software or hardware component, e.g., a FPGA or ASIC, which performs certain tasks. A module can advantageously be configured to reside on the addressable storage medium of the control system and be configured to execute one or more processes.

Other configurations of the system 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding precursors, reactants and/or gases into the reaction chamber 602. Further, as a schematic representation of a system, many components have been omitted for simplicity of illustration, and such components may include, for example, various valves, manifolds, purifiers, heaters, containers, vents, and/or bypasses.

During operation of the reactor system 600, substrates, such as semiconductor wafers (not illustrated), are transferred from, e.g., a substrate handling system to reaction chamber 602. Once substrate(s) are transferred to the reaction chamber 602, one or more gases from the gas sources 603-608, such as precursors, reactants, carrier gases, and/or purge gases, are introduced into reaction chamber 602.

It shall be understood that the following embodiments can apply to any one of the methods disclosed herein, irrespective of the precursor and/or reactant that is used in such methods, unless a corresponding embodiment would render the method in question unworkable.

In some embodiments, the HZO layer is deposited at a temperature of at least 100° C. to at most 500° C., or at a temperature of at least 150° C. to at most 450° C., or at a temperature of at least 250° C. to at most 350° C., or at a temperature of around 350° C.

In some embodiments, the precursor is provided to the reaction chamber from a precursor source maintained at a temperature of at least 25° C. to at most 200° C., or at a temperature of at least 50° C. to at most 150° C., or at a temperature of at least 75° C. to at most 125° C.

In some embodiments, the dopant compound is provided to the reaction chamber from a dopant source maintained at a temperature of at least 25° C. to at most 200° C., or at a temperature of at least 50° C. to at most 150° C., or at a temperature of at least 75° C. to at most 125° C.

In some embodiments, the oxygen compound is provided to the reaction chamber from an oxygen source maintained at a temperature of at least 25° C. to at most 200° C., or at a temperature of at least 50° C. to at most 150° C., or at a temperature of at least 75° C. to at most 125° C.

In some embodiments, the doped HZO layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

The doped HZO layer can be deposited in any suitable reactor. Thus, in some embodiments, the doped HZO layer is deposited in a cross-flow reactor. In some embodiments, the doped HZO layer is deposited in a showerhead reactor. In some embodiments, the doped HZO layer is deposited in a hot-wall reactor. Doing so can advantageously enhance uniformity and/or repeatability of doped HZO layer deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the precursor is provided to the reaction chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least −50° C. to at most 20° C., or at a temperature of at least 20° C. to at most 250° C., or at a temperature of at least 100° C. to at most 200° C.

In some embodiments, the precursor is provided to the reaction chamber by means of a carrier gas. Exemplary carrier gasses include nitrogen (N2) and a noble gas such as He, Ne, Ar, Xe, or Kr.

As an exemplary embodiment, the method as disclosed herein was performed using a system according to FIG. 6 as described herein. According to the embodiment, the precursor pulse comprises hafnium and zirconium and the dopant precursor pulse comprises Si, Al, or Ge. The following exemplary parameters were used during material deposition in the system 600:
1. Substrate temperature: 160° C.
2. Pressure in the reaction chamber: 8 Torr
3. precursor pulse (Hf and Zr): 100-150 ms
4. Purge time after precursor pulse: 40 000 ms
5. dopant pulse (Si, Al or Ge): 10 000 ms
6. Purge time after dopant pulse: 40 000 ms
7. Amount of cycles: 400

The subject matter of the present disclosure includes all novel and nonobvious combinations and sub-combinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. A method comprising:
forming, by a cyclic process, a dopant concentration gradient in a doped hafnium zirconium oxide (HZO) layer on a substrate, the cyclic process comprising:
providing the substrate in a reaction chamber;
a) pulsing one or more hafnium precursors into the reaction chamber, wherein at least a part of the substrate is contacted with the one or more hafnium precursors;
b) pulsing one or more zirconium precursors into the reaction chamber, wherein at least a part of the substrate is contacted with the one or more zirconium precursors;
c) pulsing one or more oxygen reactants into the reaction chamber, wherein at least a part of the substrate is contacted with the one or more oxygen reactants;
d) pulsing one or more dopant precursors into the reaction chamber, wherein at least a part of the substrate is contacted with the one or more dopant precursors; and
e) purging the reaction chamber.

2. The method according to claim 1, further comprising repeating one or more of operations a), b), c), d), or e), in any order, until the doped HZO layer having a first predetermined thickness is deposited on the substrate.

3. The method according to claim 2, wherein the pulsing the one or more dopant precursors into the reaction chamber further comprises depositing a first concentration of dopant elements proximate to a surface or interface of the doped HZO layer exposing the substrate to an annealing process forming the dopant concentration gradient.

4. The method according to claim 1, further comprises forming a first HZO sub-layer having a first concentration of dopant elements and a second HZO sub-layer having a second concentration of dopant elements, wherein the first concentration of dopant elements is different from the second concentration of dopant elements.

5. The method according to claim 1, wherein the forming the dopant concentration gradient comprises tuning a pulse ratio of the one or more dopant precursors versus the one or more hafnium precursors, the one or more zirconium precursors or the one or more oxygen reactants, or a combination thereof.

6. The method according to claim 1, wherein the dopant concentration in the doped HZO layer ranges between 0.0 to 20.0% from a first interface to a second interface, wherein the dopant concentration is lowest proximate the first interface and highest proximate the second interface.

7. The method according to claim 1, wherein the one or more dopant precursors comprise an element selected from a list consisting of aluminum, silicon, nickel, germanium, gallium and carbon.

8. The method according to claim 1, wherein the method further comprises forming the doped HZO layer on a seed layer comprising ZrO2 and forming a titanium oxide liner layer over the doped HZO layer.

9. A method comprising:
providing a substrate in a reaction chamber;
forming a nanolaminate structure on the substrate comprising a first hafnium zirconium oxide (HZO) sub-layer and a second hafnium zirconium oxide (HZO) sub-layer, by a cyclic process, the cyclic process comprising;
a) pulsing one or more hafnium precursors into the reaction chamber, wherein at least a part of the substrate is contacted with the one or more hafnium precursors;
b) pulsing one or more zirconium precursors into the reaction chamber, wherein at least a part of the substrate is contacted with the one or more zirconium precursors;
c) pulsing one or more oxygen reactants into the reaction chamber, wherein at least a part of the substrate is contacted with the one or more oxygen reactants; and
d) purging the reaction chamber,
wherein the first HZO sub-layer and the second HZO sub-layer comprise different concentrations of hafnium (Hf) and wherein the first HZO sub-layer and the second HZO sub-layer comprise different concentrations of zirconium (Zr).

10. The method according to claim 9, further comprising repeating one or more of operations a), b), c), or d), or a combination thereof, in any order, until the first HZO sub-layer comprising a first predetermined thickness and the second HZO sub-layer comprising a second predetermined thickness are deposited on the substrate.

11. The method according to claim 10, wherein the first HZO sub-layer is Hf rich and the second HZO sub-layer is Zr rich.

12. The method according to claim 11, further comprising doping the nanolaminate structure responsive to repeatedly pulsing one or more dopant precursors into the reaction chamber during the cyclic process, wherein at least a part of the substrate is contacted with the one or more dopant precursors.

13. The method according to claim 12, further comprising forming a dopant concentration gradient within the nanolaminate structure responsive to varying a flow rate or tuning a pulse ratio of the one or more dopant precursors versus one or more of, the one or more hafnium precursors, the one or more zirconium precursors, or the oxygen reactant, or a combination thereof.

14. The method according to claim 13, wherein the one or more dopant precursors comprises an element selected from a list consisting of aluminum, silicon, nickel, germanium, gallium and carbon.

15. The method according to claim 13, wherein forming the dopant concentration gradient within the nanolaminate structure further comprises imparting a first concentration of dopant elements into the first HZO sub-layer and imparting a second concentration of dopant elements into the second HZO sub-layer, wherein the first concentration of dopant elements is different from the second concentration of dopant elements.

16. The method according to claim 15, wherein the first concentration of dopant elements and the second concentration of dopant elements in the nanolaminate structure ranges between 0.0 to 15.0% from a first interface to a second interface within the nanolaminate structure.

17. The method according to claim 16, wherein the first concentration of dopant is lowest and proximate the first interface and the second concentration of dopant is highest proximate the second interface.

18. The method according to claim 9, further comprising forming the nanolaminate structure on a seed layer and forming a titanium oxide liner layer over the nanolaminate structure.

19. The method according to claim 18, wherein the seed layer comprises ZrO2.

20. The method according to claim 9, further comprising forming one or more additional HZO sub-layers each having a different concentration of dopant elements from at least one other HZO sub-layers.
